(19) United States
(12) Patent Application Publication
(10) Pub. No.: US 2005/0121806 A1
(43) Pub. Date: Jun. 9, 2005

(54) Method for attaching circuit elements

(75) Inventor: James A. Sangiorgi, Phoenix, AZ (US)

Correspondence Address: Squire, Sanders & Dempsey L.L.P.;Two Renaissance Square, Suite 2700, 40 North Central Avenue, Phoenix, AZ, 85004-4498, US

(73) Assignee: White Electronic Designs Corporation

(21) Appl. No.: 10/729,705

(22) Filed: Dec. 4, 2003

(51) Int. Cl. H01L 23/28

(52) U.S. Cl. 257/787; 156/314

(57) ABSTRACT

A process for attaching a circuit element such as a capacitor to a substrate includes applying a conductive bonding material to electrical connections of the circuit element and/or substrate; placing the circuit element in position over the substrate; seating the circuit element in the conductive bonding material on the substrate; heating the bonding material to form a conductive bond; and applying a low viscosity wicking material around the area of the circuit element near the substrate. In some embodiments the conductive bonding material is a conductive epoxy such as silver or gold epoxy and the low viscosity wicking material is a flip chip underfill encapsulant.

### FIELD OF THE INVENTION

The present invention relates to fabrication of circuits and/or circuit boards. More particularly, but not exclusively, the present invention describes improved methods for attaching circuit elements in a circuit assembly.

### BACKGROUND OF THE INVENTION

There are a variety of conventional methods for bonding circuit elements such as resistors, capacitors, inductors, diodes, and semiconductor elements to a substrate or printed circuit board (PCB).

One method for attaching a semiconductor device, such as an integrated circuit die, to a substrate is disclosed in U.S. Pat. No. 6,498,400 to Yamakawa et al. Yamakawa discloses using a hot melt adhesive sheet having spacer to bond a circuit element to a circuit assembly. The hot melt adhesive includes an adhesive such as a silicone-modified epoxy resin adhesive, a silicone adhesive, and/or a silicone-modified polyimide adhesive. The hot melt adhesive is displaced onto the substrate before the circuit element is placed on the circuit assembly.

U.S. Pat. No. 4,661,192 to McShane discloses electrically connecting an integrated circuit die to a lead frame using a conductive epoxy. The conductive epoxy provides an electrical bond between electrical leads of the circuit components and the metallic pads or “landing areas” of the PCB.

Other conventional techniques for attaching circuit components to a circuit board include soldering or wire bonding the electrical connections. In many instances a non-conductive adhesive is placed on the substrate before placement of the circuit element to provide a non-conductive bond between non-conductive portions of the circuit element and the board or substrate.

Turning to FIGS. 1A and 1B, a method for attaching a circuit element 10 to a circuit board 20 according to the related art includes: (i) applying a conductive bonding material 30 to the electrical terminals 12 of circuit element 10 and/or the conductive pads 24 of the circuit board 20; (ii) positioning element 10 onto board 20 in a manner that the electrical connections (i.e., terminals 12 and pads 24) of element 10 and board 20 are properly aligned; and (iii) applying heat to the circuit assembly to promote formation of a conductive bond 25 (FIG. 1B) between terminals 12 and landing areas 24 from conductive bonding material 30.

Circuit element 10 is an electrical element such as a capacitor, inductor, diode, transistor or resistor, which is electrically connected to circuit board 20 and includes a body 11 and one or more terminals 12 (additionally referred to herein as “terminations”) for establishing electrical connection with board 20.

The circuit board 20 in the illustrated example includes a laminate substrate 22 having one or more metallized or pre-tinned conductor lands or pads 24 (also referred to as “landing areas”) for establishing electrical connection with terminations 12 of circuit element 10. Conductive bonding material 30 is a material such as a conductive adhesive (e.g., silver or gold epoxy) or solder and is applied to one or both of pads 24 and/or terminations 12. When heat is applied to bonding material 30 and it is allowed to cool, a rigid electrically conductive bond 35 results (for example, solder flows and hardens and/or conductive epoxy is cured).

As shown in FIG. 1B pads 24 and/or bonding material 30 may elevate circuit element 10 above the laminate substrate 22 resulting in a gap 40. Consequently, circuit element 10 may only be supported by, and/or connected to, board 20 by its electrical connections. This arrangement potentially results in an unstable and/or relatively fragile mounting of element 10 on board 20.

To provide additional bonding strength, referring to FIGS. 2A and 2B, another method of the related art proposes applying a second, non-conductive adhesive 50 (e.g., a chip bonder) at room temperature between areas of the element body 11 and substrate 22 (i.e., where gap 40 exists) before element 10 is put in place. When dried and/or cured, adhesive 50 forms an additional bond between circuit element 10 and substrate 22 and thus the shear strength of the overall bond between element 10 and board 20 is increased.

This conventional method, for example, where two strips of conductive epoxy are applied to attach the terminations 12 to the landing areas 24 and a strip of non-conductive epoxy 50 is applied to attach the circuit element body 11 to the substrate, suffers from one or more of the following problems.

When the finished part or assembly is subjected to subsequent thermal cycling, the chip bonder 50 has been shown to expand and potentially cause a disconnect between the circuit element terminations 12 and the board landing areas 24. Thermal expansion of the chip bonding adhesive during thermal cycling additionally may result in a loss bond shear strength.

Conventional non-conductive adhesives, such as chip bonders, have low glass transition temperatures (Tg) which inhibits the adhesive's ability to absorb stress resulting from thermal cycling. The non-conductive epoxy has a high coefficient of thermal expansion (C.T.E.) that emphasizes stress in the Z-axis (i.e., the direction perpendicular to the substrate) during thermal cycling. It is the stress in the Z-axis that tends to lift the circuit element from the circuit board and sever its electrical connections.

Consequently, it would be desirable to have a process for attaching circuit elements to a substrate with greater shear strength than the shear strength of bonds achieved from element attachment using soldering or conductive epoxy alone. Additionally, it would be desirable to have a process for attaching circuit elements to a substrate with a greater reliability and lower tendency to disconnect and/or lose shear strength when subject to thermal cycling as compared to element attachment using chip bonding adhesives.

### SUMMARY OF THE INVENTION

The present invention alleviates one or more of the foregoing problems by a process for attaching a circuit element to a substrate including: applying a conductive bonding material to conductors of the circuit element and/or substrate; placing the circuit element in position over the substrate; seating the circuit element on the substrate via the conductive bonding material; heating the bonding material to promote formation of a conductive bond; and while heating, applying a low viscosity encapsulant around the area of the circuit element near the board.

According to certain embodiments of the present invention, the conductive bonding material is a conductive epoxy. In other embodiments of the present invention, the conductive bonding material is solder.

According to various other aspects of the invention, the low viscosity encapsulant is a flip chip underfill material.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIGS. 1A and 1B are side views of a circuit assembly using an element attach technique of the related art.

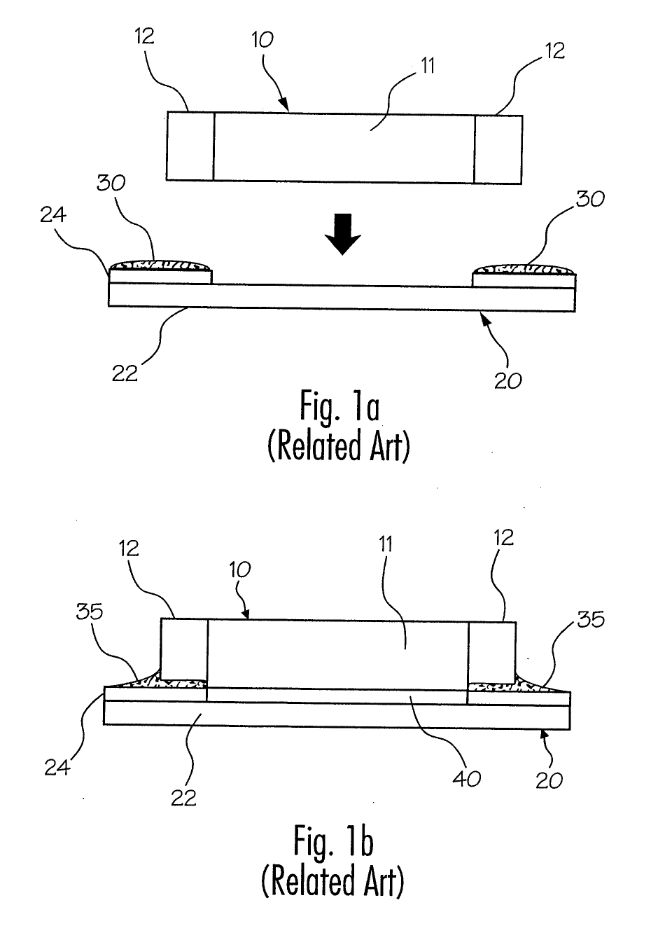

FIGS. 2A and 2B are side views of a circuit assembly using another element attach technique of the related art.

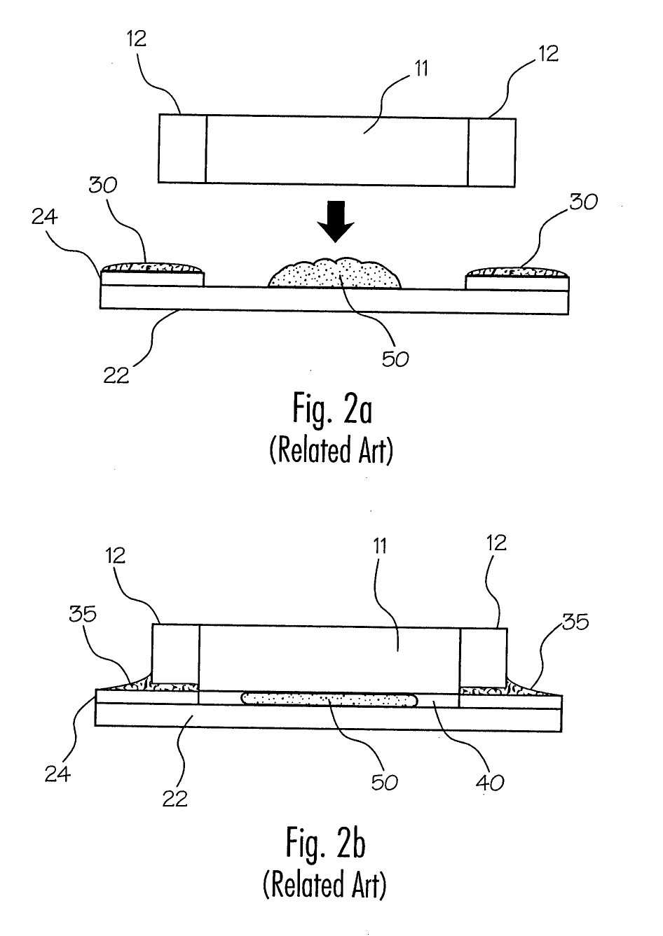

FIG. 3 is a flow diagram for a method of attaching circuit elements to a substrate according to one embodiment of the present invention.

FIGS. 4A, 4B and 4C are side views of a circuit assembly during various stages of the method for attaching circuit elements shown in FIG. 3.

FIG. 5 is a flow diagram for a method of attaching circuit elements to a substrate according to another embodiment of the present invention.

### DESCRIPTION OF THE EMBODIMENTS

Reference will now be made in detail to the present exemplary embodiments of the invention, examples of which are illustrated in the accompanying drawings. Wherever possible, the same reference numbers will be used throughout the drawings to refer to the same or like parts.

A method for forming a circuit assembly by attaching a circuit element to a desired location (e.g., substrate, printed circuit board, lead frame, or other semi-permanent mounting surface) in accordance with one or more methods of the present invention provides greater bond shear strength than attaching circuit elements using conductive bonds alone. Moreover, the methods of the present invention produce a circuit assembly which is less susceptible to circuit element disconnect than conventional methods using non-conductive epoxy. Additionally, a circuit element attached to a substrate in accordance with the inventive methods has a shear strength that is not significantly altered by thermal cycling.

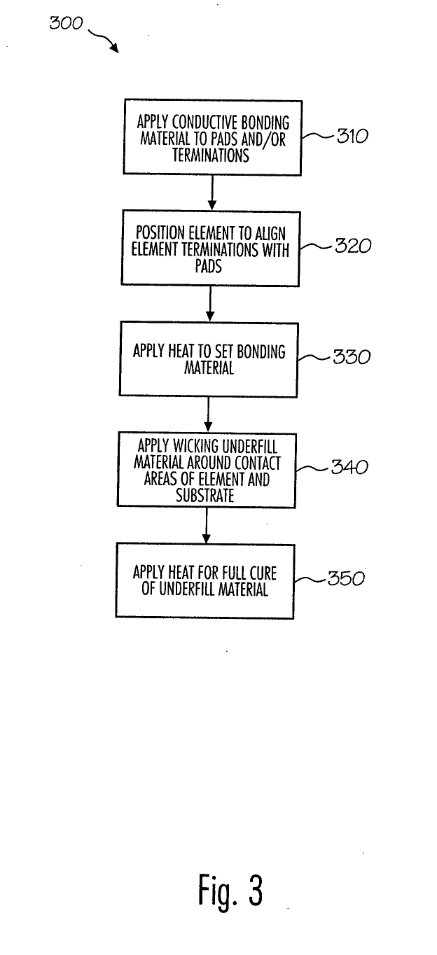

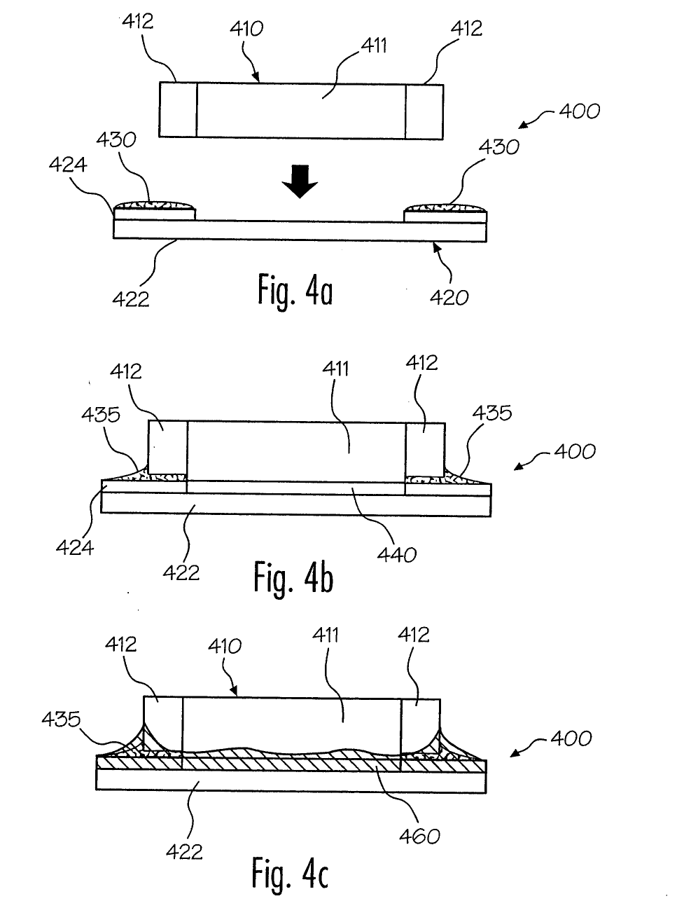

Turning to FIGS. 3 and 4, a method 300 (FIG. 3) of forming a circuit assembly 400 (FIGS. 4A, 4B and 4C) by attaching a circuit element 410 to a desired location 420 includes: applying 310 an amount of conductive bonding material 430 to electrical conductors 412 of the circuit element 410 and/or the landing areas 424 at the desired circuit element location 420; positioning 320 the circuit element 410 at the desired location 420 (e.g. on substrate 422); heating 330 at least a portion of the assembly 400 to promote formation of a conductive bond 435; and applying 340 an amount of non-conductive underfill encapsulant 460 around the circuit element 410; and heating 350 to promote formation of a non-conductive bond.

The amount and timing for applying the conductive bonding material 430 varies depending on the type of material used. For example, if conductive bonding material 430 is a conductive epoxy, such as a gold or silver epoxy, the epoxy may be applied before positioning element 410 in place on substrate 422 (i.e., where terminations 412 are aligned with and contact landing areas 424). Alternatively, if bonding material 430 is a conductive solder, then a solder flux may be placed on the electrical connections prior to positioning and placement of the circuit element 410 on substrate 422, and the solder may be applied before or after circuit element 410 is in position. If solder paste is used for bonding material 430, it may be applied prior to placement of circuit element 410 on substrate 422.

In any event, solder or conductive epoxy 430 both utilize elevated temperatures to promote formation of a conductive bond 435 (FIG. 4B). That is, at least a portion of the assembly 400 and/or bonding material 430 is heated to flow solder or gel cure the conductive epoxy. Heating 330 may be performed in accordance with conventional techniques for forming the conductive bonds 435. For example, solder reflow may be achieved using infrared, vapor phase or hot air convection oven reflow methods. In preferred embodiments, where conductive epoxy is used for conductive bonding material 430, the circuit assembly is heated on a hot plate to promote a snap-cure or gel-cure of the conductive epoxy.

When element 410 is positioned 320 at its desired location 420 (e.g., on substrate 422 with terminations 412 aligned on pads 424), preferably, although not necessarily, a slight gap 440 exists between the body 411 of circuit element 410 and an opposing surface of substrate 422. The heat applied during formation of the conductive bonds 435 and the existence of this slight gap 440 between body 411 and substrate 422 result in a situation where additional bonding (i.e., forming bonds in addition to the conductive bonds 435) may be achieved using a low viscosity underfill encapsulant 460 and without significant changes in assembly steps or device handling.

Low viscosity underfill material 460 is preferably a non-conductive encapsulant selected to have good wicking characteristics at the temperature ranges used during soldering or snap curing of conductive epoxy. In preferred embodiments of the invention, material 460 is an underfill encapsulant used for flip-chip applications.

A preferred underfill material in accordance with one aspect of the present invention is a high purity, low stress liquid epoxy encapsulant designed for enhanced adhesion to integrated circuit passivation materials. Preferred underfill materials are selected to rapidly underfill devices with as little as ½ mil gap at temperatures in the range of 80° C. to 140° C. Uncured properties of an example underfill material at 25° C., Cone and plate (Brookfield, cps) CP52; speed 20 include a viscosity in the range of 2000-2,500 centipoises. One preferred underfill material included the following cured characteristics:
a Coefficient of Linear Thermal Expansion (C.T.E) of 45_ppm/° C. (Alpha 1) and 143_ppm/° C. (Alpha 2),
an extractable ionic content of less than 10 ppm for Chloride or Sodium;
a Glass Transition Temperature (Tg) of approximately 140° C.; and/or
a flexural modulus at 25° C. of approximately 5.6 GPa.

Advantages of using an underfill encapsulant, as opposed to a chip bonding adhesive, in the methods of the present invention include: (i) the underfill material has a lower viscosity as compared to conventional bonding adhesives (and thus a greater ability to spread through small spaces or gaps); (ii) the ability of the underfill material to wick up and under the sides of the circuit element 410 during low to moderate heating temperatures (which may result in an increase in bonding surface area between element 410 and substrate 422 than as compared to traditional chip bonding adhesives); (iii) a greater wetting ability of the underfill material to element 410 and substrate 422; (iv) a greater glass transition temperature (Tg) of the underfill increases the ability of the material to absorb stress and thus allows for greater variation of temperatures and longer durations for thermal cycling; (v) a uniform filler shape and size allow a higher flow rate of underfill material as compared to conventional adhesives; (vi) the medium to high elastic modulus of the underfill material absorbs the strain caused by the mismatch of the coefficient of thermal expansion (C.T.E.) between circuit element 410 and substrate 422; and (vii) the C.T.E. of the underfill material may be closer matched to the C.T.E. of the conductive epoxy, substrate and/or element body, thus the strain in the Z-axis during thermal cycling may be reduced.

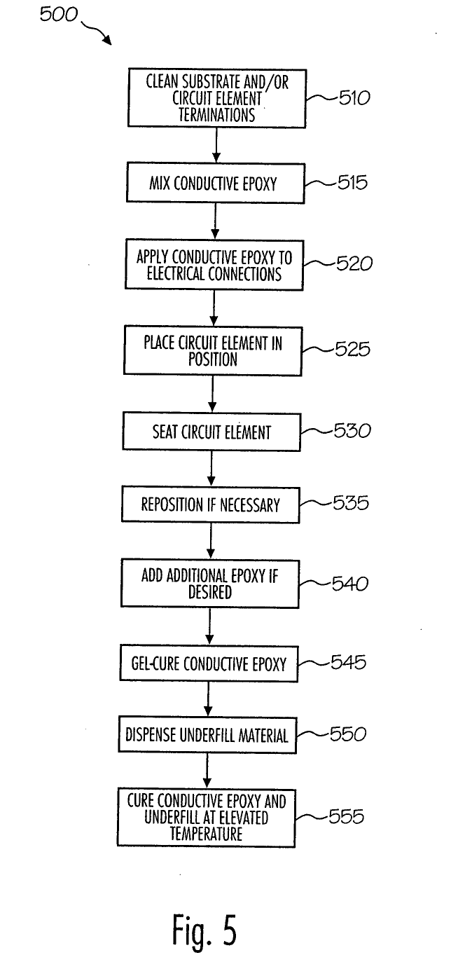

Referring to FIG. 5, an exemplary method 500 for attaching circuit elements to a substrate includes: cleaning 510 the substrate and/or circuit element terminals if desired; if needed, mixing 515 conductive epoxy resin (preferably in accordance with the manufacturer's specifications); applying 520 an amount of the conductive epoxy to the landing areas on the circuit board and/or circuit element terminals; placing 525 the circuit element in position over the landing areas; seating 530 the circuit element on the substrate by pressing it down with a finger or soft implement; repositioning 535 the circuit element if necessary; optionally, adding 540 an additional amount of conductive epoxy to cover exposed conductor surfaces; gel curing 545 conductive epoxy at an elevated temperature; dispensing 550 a low viscosity encapsulant around and under the circuit element near the substrate surface; and curing 555 the conductive epoxy and underfill material at an elevated temperature to achieve a rigid bond. Additional cleaning (not shown) may be subsequently performed if desired.

Cleaning 510 may be performed in any manner to remove debris and contaminates from the substrate landing areas and/or circuit element terminals. In the preferred embodiment cleaning 510 is an isopropyl alcohol clean. Certain epoxies require mixing two individual components to form the epoxy while other epoxies are available as a single material. Accordingly, if needed, the conductive epoxy is mixed 515 before application 550 of conductive epoxy to assembly 400.

The conductive epoxy resin used for the present invention is preferably selected to be compatible with the type of conductors subject to bonding (e.g., gold conductors bonded with gold epoxy and silver conductors with silver epoxy) and may be applied 520 in any manner suitable to dispense an amount of epoxy resin to a desired area. This may include for example, manual or automated dispensing using a brush, blotter or syringe (e.g., a pneumatically assisted hypodermic syringe). Screen printing the conductive epoxy in the appropriate areas, similar to solder paste screen printing, may also be used to apply the conductive epoxy.

Circuit element 410 is placed 525 and seated 530 and repositioned 535, if necessary, on substrate 422. Placement of circuit element 410 may be performed manually or by an automated machine such as a pick and place machine. Additional conductive bonding material may be applied 540 if desired to provide additional conductive bonding of terminals 412 with landing areas 424.

In preferred embodiments, although not required, the conductive epoxy is snap cured to a gel consistency (referred to as “gel cured”) at an elevated temperature (for example, between 65° C. and 85° C. for 10-12 minutes). Gel curing the conductive epoxy may be performed using a hot plate or other method for heating a circuit assembly. Heating the circuit assembly on a hot plate may be advantageous over alternate methods for heating, such as using a convection oven, because the user (or automated machine) may readily access the circuit assembly during heating for application 550 of the underfill material.

The underfill material is dispensed 550 around the circuit element preferably after the conductive epoxy has cured to a gel consistency but at a similar elevated temperature which facilitates the gel cure of the conductive epoxy. Application of the underfill material at this elevated temperature promotes the wicking of the material to fill gap 440 (FIG. 4b) and gelling of the underfill material from its liquid application form.

Assembly 400 is then cured 555 at an increased elevated temperature to promote full curing of the conductive epoxy and underfill material. Full curing 555 may be performed using a convection oven or other method for raised temperature curing. In preferred embodiments the full cure may be performed in a convection oven at a temperature range of 155° C. to 175° C. for a period of approximately ninety minutes.

It should be recognized that the gel cure and full cure temperatures and durations for the conductive epoxy and/or underfill material will depend on the amount and type of the bonding materials used and corresponding manufacturer's recommended specifications.

The following example details the production, testing and comparison of (i) circuit assemblies built in accordance with the methods of the present invention; and (ii) and circuit assemblies fabricated according to the techniques of the related art.

### EXAMPLE

Two materials (an underfill encapsulant and a chip bonder (i.e., non-conductive epoxy)) were comparison tested for staking a chip capacitor to a laminate substrate. Seven test boards were built with board #4 serving as a control specimen in which the capacitor was attached without staking (i.e., no bonding other than the conductive bonds) and without being subjected to temperature cycling. The capacitor was sheared from Board 4 to determine the shear strength of the conductive bonds not yet subject to temperature cycling.

The substrates built, some of which were subjected to multiple temperature cycles of −65° C. to 150° C., are identified in the following table:

TABLE 1

| | Conductive | | |
|---|---|---|---|
| Board # | Attachment | Staking | Temp Cycles |
| 1 | Ag (Silver) filled | Underfill encapsulant | 140X |
| | epoxy | | |
| 2 | Ag filled epoxy | Underfill encapsulant | None |
| 3 | Ag filled epoxy | None | 140X |
| 4 | Ag filled epoxy | None | None |
| 5 | Ag filled epoxy | Chip bonder | 140X |
| 6 | Ag filled epoxy | Chip bonder | None |
| 7 | Ag filled epoxy | None | 140X |

Substrates #1, #3, #5 and #7 were subjected to multiple temperature cycles. During the first few sets of ten temperature cycles, the capacitance from each capacitor was probed from the back of the substrates to ensure each capacitor was still electrically connected.

Substrates #2 and #6 were staked and sheared without any temperature cycling so that the degradation of shear strength due to temperature cycling could be evaluated. After temperature cycling of relevant boards, all capacitors were sheared from their boards and the following observations were determined.

The shear test demonstrated that the chip bonder (i.e., non-conductive epoxy) significantly degraded after temperature cycling. The shear strength for capacitors staked with the non-conductive epoxy was nearly the same as the shear strength of a capacitor that had not been staked at all. By way of contrast, the shear strength of the capacitor staked with the underfill material after temperature cycling, was very similar to its shear strength prior to temperature cycling.

Accordingly, it was observed that use of an underfill encapsulant was superior to the use of non-conductive epoxies for staking non-integrated circuit elements, such as capacitors, inductors, resistors, diodes, transistors and mechanical switches or relays, to a substrate or circuit board.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A method for attaching a circuit element to a substrate, comprising:
applying a conductive bonding material to a conductive portion of at least one of the circuit element and the substrate;
positioning the circuit element in a desired location on the substrate;
heating the conductive bonding material to promote one or more conductive bonds; and
applying a non-conductive bonding material around an area where the circuit element overlies the substrate to form a non-conductive bond between the circuit element and the substrate.

2. The method of claim 1 wherein the conductive bonding material comprises a conductive epoxy resin.

3. The method of claim 1 wherein the non-conductive bonding material comprises a liquid underfill encapsulant material.

4. The method of claim 1 wherein the circuit element is one selected from the group consisting of a capacitor, a resistor, a diode, a transistor and an inductor.

5. The method of claim 1 wherein heating the conductive bonding material comprises placing the substrate on a hot plate and heating the substrate to a temperature in a range of approximately 65° C. to 85°.

6. The method of claim 1 wherein the substrate comprises a laminate substrate and wherein the conductive bonding material comprises a conductive epoxy resin.

7. The method of claim 1 wherein the substrate comprises a laminate substrate and wherein the conductive bonding material comprises a conductive solder.

8. The method of claim 1 wherein the substrate comprises a laminate substrate and wherein the non-conductive bonding material comprises a flip chip underfill material.

9. A method of attaching an electrical device to a circuit board, comprising:
applying a conductive adhesive to electrical conductors of at least one of the electrical device and the circuit board;
positioning the electrical device relative to the circuit board so that corresponding electrical conductors are aligned and in contact;
seating the electrical device in the conductive adhesive;
gel curing the conductive adhesive at an elevated temperature;
applying an amount of liquid encapsulant material around edges of the electrical device near the circuit board; and
full curing the conductive adhesive and the encapsulant material.

10. The method of claim 9 wherein the electrical device is one selected from the group consisting of a resistor, a capacitor, a diode, a transistor and an inductor.

11. The method of claim 9 wherein the liquid encapsulant material comprises a flip chip underfill material.

12. The method of claim 9 wherein the conductive adhesive comprises a silver epoxy resin.

13. The method of claim 9 wherein the conductive adhesive comprises a gold epoxy resin.

14. The method of claim 9 wherein the circuit board comprises a laminate substrate.

15. An electrical circuit assembly comprising:
a substrate;
at least one circuit element bonded to the substrate via a conductive bond and a non-conductive bond, wherein the conductive bond comprises a solidified conductive epoxy resin and wherein the non-conductive bond comprises an underfill encapsulant material.

16. The electrical circuit assembly of claim 15 wherein the substrate comprises a laminate substrate and wherein the at least one circuit element comprises an electrical circuit device other than an integrated circuit.

17. The electrical circuit assembly of claim 15 wherein the at least one circuit element comprises a device selected from the group consisting of a capacitor, a resistor, an inductor, a transistor and a diode.
